(19) United States
(12) Patent Application Publication
(10) Pub. No.: US 2025/0346538 A1
(43) Pub. Date: Nov. 13, 2025

(54) CORROSION-RESISTANT MEMBER

(71) Applicant: KYOCERA Corporation, Kyoto-shi, Kyoto (JP)

(72) Inventors: Kazuhiro ISHIKAWA, Gamo-gun, Shiga (JP); Tomoki TANIGUCHI, Echi-gun, Shiga (JP)

(21) Appl. No.: 18/998,755

(22) PCT Filed: Jul. 19, 2023
(86) PCT No.: PCT/JP2023/026341

§ 371 Date: Jan. 27, 2025

(30) Foreign Application Priority Data
Jul. 27, 2022 (JP) 2022-119708

(51) Int. Cl. C04B 41/52; C04B 35/10; C04B 41/50; C04B 41/87; C04B 41/89

(52) U.S. Cl. CPC C04B 41/52; C04B 35/10; C04B 41/5031; C04B 41/5045; C04B 41/87; C04B 41/89

(57) ABSTRACT

A corrosion-resistant member according to the present disclosure is a laminate body including a base and a first layer layered on the base. The first layer is composed of a rare earth element compound containing, as a main constituent, a rare earth element that is a metal element. In the first layer, a crystallinity of a region close to the base is lower than a crystallinity of a region far from the base. A corrosion-resistant member according to the present disclosure is a laminate body including a base, a compound layer layered on the base and composed of a metal element M, and a first layer layered on the compound layer. The first layer is composed of a rare earth element compound containing, as a main constituent, a rare earth element that is a metal element. The compound layer has a uniform crystallinity. In the first layer, a crystallinity of a region close to the base is lower than a crystallinity of a region far from the base.

### TECHNICAL FIELD

The present disclosure relates to a corrosion-resistant member.

### BACKGROUND OF INVENTION

As a corrosion-resistant member, for example, a component described in Patent Document 1 is known. The component described in Patent Document 1 includes a base member (base) and a composite film provided on the base member. The composite film contains amorphous YₓAl_{y}O_{z} (where 0.24≤x/(x+y)≤0.82 and z/(x+y)=1.5). This composite film is manufactured by vaporizing each raw material of yttrium oxide and aluminum oxide in a state where the base member is heated to a predetermined temperature in a range from 250° C. to 600° C., and injecting the vaporized raw materials to the base member using a carrier gas.

### CITATION LIST

### Patent Literature

Patent Document 1: WO 2021/002339

### SUMMARY

A corrosion-resistant member according to the present disclosure is a laminate body including a base, and a first layer layered on the base. The first layer is composed of a rare earth element compound, containing, as a main constituent, a rare earth element that is a metal element. In the first layer, a crystallinity of a region close to the base is lower than a crystallinity of a region far from the base.

A corrosion-resistant member according to the present disclosure is a laminate body including a base, a compound layer layered on the base and composed of a metal element M, and a first layer layered on the compound layer. The first layer is composed of a rare earth element compound, which contains, as a main constituent, a rare earth element that is a metal element. The compound layer has a uniform crystallinity. In the first layer, a crystallinity of a region close to the base is lower than a crystallinity of a region far from the base.

A corrosion-resistant member according to the present disclosure is a laminate body including a base, a compound layer layered on the base and composed of a metal element M, and a first layer layered on the compound layer. The first layer is composed of a rare earth element compound, which contains, as a main constituent, a rare earth element that is a metal element. An atomic number of the metal element M contained in the compound layer is smaller than an atomic number of the rare earth element contained in the first layer as the main constituent. In the first layer, a crystallinity of a region close to the base is lower than a crystallinity of a region far from the base.

### BRIEF DESCRIPTION OF THE DRAWINGS

FIG. 1 is a cross-sectional view illustrating a corrosion-resistant member according to a non-limiting embodiment of the present disclosure.

FIG. 2 is a cross-sectional view illustrating a corrosion-resistant member according to a non-limiting embodiment of the present disclosure.

FIG. 3 is a cross-sectional view illustrating a corrosion-resistant member according to a non-limiting embodiment of the present disclosure.

FIG. 4 is a cross-sectional view illustrating a corrosion-resistant member according to a non-limiting embodiment of the present disclosure.

FIG. 5 is a cross-sectional view illustrating a corrosion-resistant member according to a non-limiting embodiment of the present disclosure.

FIG. 6 is a cross-sectional view illustrating a corrosion-resistant member according to a non-limiting embodiment of the present disclosure.

FIG. 7 is a schematic view illustrating a sputtering device for obtaining a corrosion-resistant member according to a non-limiting embodiment of the present disclosure.

FIG. 8 is a partially enlarged photograph captured by a TEM in Example 1.

FIG. 9 is an electron diffraction image of a surface side (NBD1) in a Y₂O₃ layer in Example 1.

FIG. 10 is an electron diffraction image of a base side (NBD2) in the Y₂O₃ layer in Example 1.

### DESCRIPTION OF EMBODIMENTS

The component described in Patent Document 1 has a problem in that the corrosion resistance is worse than that of a crystalline film, since the film is made of only an amorphous material.

The present disclosure provides a corrosion-resistant member that improves the corrosion resistance and improves the bonding strength between a base and a film.

According to the corrosion-resistant member of the present disclosure, the corrosion resistance is improved and the bonding strength between the base and the film is improved.

### Corrosion-Resistant Member

Corrosion-resistant members 1A to 1F according to non-limiting embodiments of the present disclosure will be described below in detail with reference to the drawings. However, for convenience of description, each of the drawings referenced below illustrates, in a simplified manner, only main members necessary for description of the embodiments. Therefore, the corrosion-resistant members 1A to 1F may include any constituent member that is not illustrated in each of the drawings referenced below. The dimensions of the members in each of the drawings do not faithfully represent the actual dimensions of the constituent members, the dimension ratios of the respective members, or the like.

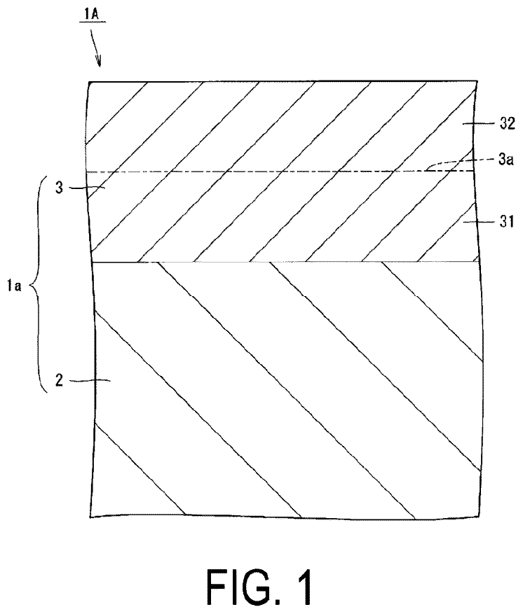

As in the example illustrated in FIG. 1, the corrosion-resistant member 1A is a laminate body 1a including a base 2 and a first layer 3 layered on the base 2. The first layer 3 is composed of a rare earth element compound, which contains, as a main constituent, a rare earth element that is a metal element. In the first layer 3, a crystallinity of a region 31 close to the base 2 is lower than a crystallinity of a region 32 far from the base 2. In this case, the corrosion resistance is improved, and the bonding strength between the base 2 and the film (first layer 3) is improved. The reason for this is presumed as follows.

The base 2 is made of any one of a ceramic, a single crystal, a glass, and a metal. When the material of the base 2 is a ceramic, examples of the main constituent include alumina, silicon nitride, silicon carbide, and zirconia. In the case of a single crystal, examples of the single crystal include sapphire, silicon, and YAG (Y₃Al₅O₁₂). In the case of a glass, examples of the glass include quartz glass. Examples of a metal include Al and stainless steel.

When a description is made using an example in which the material of the base 2 is a ceramic, the ceramic (base 2) is made of a polycrystalline sintered body. A crystal in the ceramic is bonded to a portion, of the first layer 3, having a low crystallinity. When the crystal is bonded to the portion, of the first layer 3, having the low crystallinity, lattice defects, generated in a bonding portion between the crystal in the ceramic and the portion, of the first layer 3, having the low crystallinity, are reduced. Therefore, the bonding strength between the base 2 and the first layer 3 is improved.

Rare earth element compounds such as Y₂O₃ are excellent in terms of corrosion resistance. The higher the crystallinity of the rare earth element compound, the better the corrosion resistance. Since the region 32, of the first layer 3, far from the base 2 has a high crystallinity, the region 32 is excellent in terms of corrosion resistance. Thus, a surface side of the first layer 3 (rare earth oxide) of the corrosion-resistant member 1A is excellent in terms of corrosion resistance.

Note that “corrosion resistance” means, for example, having excellent corrosion resistance against a corrosive gas plasma and having little detachment or the like of particles from the surface. “Main constituent” means a constituent having the largest value of mass % as compared with other constituents. The main constituent may be, for example, 80 mass % or greater.

The laminate body 1a may be rephrased as a first laminate body 1a. The first layer 3 may be rephrased as a rare earth element compound layer. The rare earth element compound may be simply referred to as a rare earth compound. Note that the first layer 3 may be simply referred to as a film.

Examples of the rare earth element contained in the first layer 3 as the main constituent include Y, La, Nd, Sm, Eu, Gd, Dy, and Ho.

Whether or not the main constituent contained in the first layer 3 is a rare earth element may be measured (confirmed) using an energy dispersive X-ray analyzer (EDS) attached to a transmission electron microscope (TEM). Whether or not, in the first layer 3, the crystallinity of the region 31 close to the base 2 is lower than the crystallinity of the region 32 far from the base 2 may be measured by electron diffraction using the TEM.

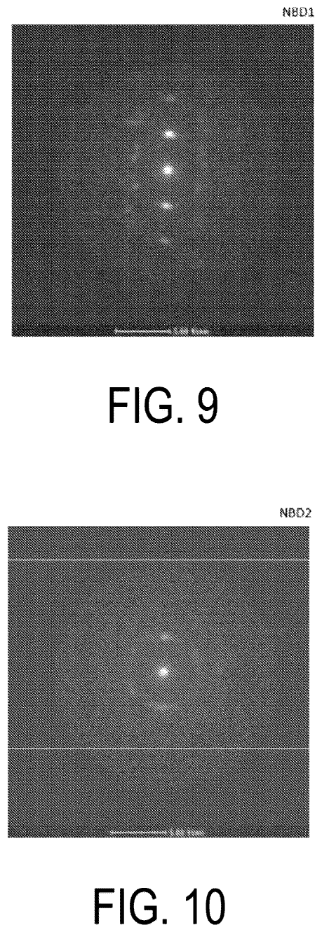

Here, the crystallinity will be described using a specific example. FIGS. 8 to 10 show measurement results of Example 1 described later. As shown in FIGS. 8 and 10, in a region (NBD2) close to the base, since the number of concentric Debye-Scherrer rings observed by electron diffraction is small and the contour of each concentric circle is relatively unclear, the crystallinity is low. On the other hand, as shown in FIGS. 8 and 9, in a region (NBD1) far from the base, since the number of concentric Debye-Scherrer rings observed by electron diffraction is larger than that in the region (NBD2) close to the base, and the contour of each concentric circle is clear, the crystallinity is higher than that in the region (NBD2) close o the base.

The higher the crystallinity, the more clearly the contour of each concentric circle of the concentrically formed Debye-Scherrer ring observed by electron diffraction is identified. The lower the crystallinity, the less clearly the contour of each concentric circle of the concentrically formed Debye-Scherrer ring observed by electron diffraction is identified. Thus, it becomes difficult to identify the contour. When the crystallinity is uniform, between the region close to the base and the region far from the base, the arrangement of the Debye-Scherrer rings observed by electron diffraction and the clearness of the contour are substantially the same.

The region 31 close to the base 2 may be closer to the base 2 than a center 3a in the thickness direction of the first layer 3. The region 32 far from the base 2 may be farther from the base 2 than the center 3a in the thickness direction of the first layer 3. Note that the region 31 close to the base 2 may be rephrased as a first region 31, and the region 32 far from the base 2 may be rephrased as a second region 32.

The first layer 3 may be exposed to the surface of the corrosion-resistant member 1A. Rare earth element compounds such as Y₂O₃ are excellent in terms of corrosion resistance. The higher the crystallinity of the rare earth element compound, the better the corrosion resistance. Since the region 32, of the first layer 3, far from the base 2 has a high crystallinity, the region 32 is excellent in terms of corrosion resistance. Thus, when the first layer 3 is exposed, the corrosion-resistant member 1A becomes excellent in terms of corrosion resistance.

The rare earth element compound may be an oxide. Oxides (such as Y₂O₃ and Y₃Al₅O₁₂) are excellent in terms of corrosion resistance against a corrosive gas plasma. Thus, corrosion resistance can be maintained for a long period of time. “Oxides” include “composite oxides”.

The main constituent of the base 2 may be alumina (Al₂O₃). The first layer 3 may contain an oxide of Y as the main constituent and may further contain a composite oxide of Y and Al. “Oxide of Y” may be either crystalline or amorphous, or may be both crystalline and amorphous.

When the main constituent of the base 2 is alumina, the chemical bonding force with a compound containing Y as a metal element is high. Thus, the bonding strength between the base 2 and the first layer 3 containing the oxide of Y as the main constituent is improved. When the first layer 3 contains the oxide of Y as the main constituent, the corrosion resistance of the film is improved. When the first layer 3 further contains the composite oxide of Y and Al, the composite oxide of Y and Al contained in the first layer 3 is chemically strongly bonded to the main constituent (Al₂O₃) of the base 2. Thus, the bonding strength between the base 2 and the first layer 3 is improved.

Examples of the composite oxide of Y and Al include YAlO₃ (Y₂O₃:Al₂O₃=1:1 (YAM)), Y₄Al₂O₉ (Y₂O₃:Al₂O₃=2:1 (YAP)), and Y₃Al₅O₁₂ (Y₂O₃:Al₂O₃=3:5 (YAG)).

The measurement of whether or not the first layer 3 contains the oxide of Y as the main constituent and the measurement of whether or not the first layer 3 further contains the composite oxide of Y and Al may be performed using the EDS attached to the TEM, or may be performed by electron diffraction using the TEM.

When the main constituent of the base 2 is alumina, the main constituent may contain at least one of silicon, magnesium, and calcium as an oxide. The components constituting the base 2 may be identified by an X-ray diffractometer using a CuKα beam. The content of each of the identified components can be determined by using, for example, an inductively coupled plasma (ICP) emission spectrophotometer, or a fluorescent X-ray analysis device.

The average thickness of the first layer 3 may be from 1 nm to 1100 nm. The thickness of the first layer 3 may be measured by cross-sectional observation using an electron microscope. For example, the thickness may be measured at five or more measurement points at arbitrary positions of the first layer 3, and an average value thereof may be calculated. Examples of the electron microscope may include a scanning electron microscope (SEM) and a TEM.

The corrosion-resistant member 1B according to a non-limiting embodiment of the present disclosure will be described. Differences of the corrosion-resistant member 1B from the corrosion-resistant member 1A will be mainly described below, and detailed descriptions of elements having the same configuration as that of the corrosion-resistant member 1A may be omitted. Therefore, the description related to the corrosion-resistant member 1A may be used to understand the configuration of the corrosion-resistant member 1B. These points will be similarly applied to the corrosion-resistant members 1C to 1F described later.

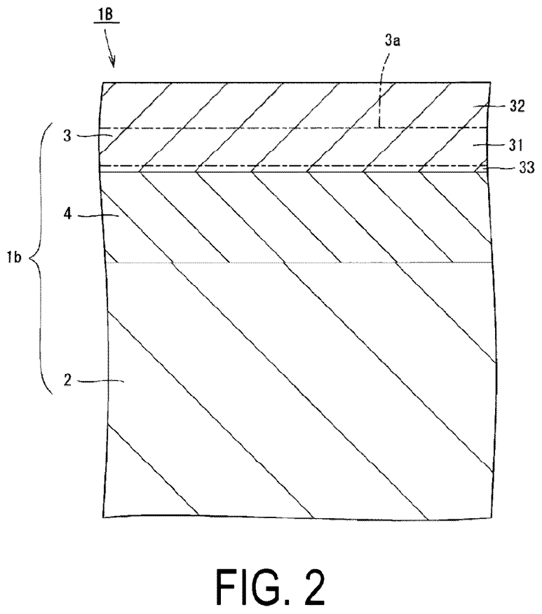

As in the example illustrated in FIG. 2, the corrosion-resistant member 1B is a laminate body 1b including the base 2, a compound layer 4 layered on the base 2 and composed of a metal element M, and the first layer 3 layered on the compound layer 4. The first layer 3 is composed of a rare earth element compound, which contains, as a main constituent, a rare earth element that is a metal element. The compound layer 4 has a uniform crystallinity. In the first layer 3, the crystallinity of the region 31 close to the base 2 is lower than the crystallinity of the region 32 far from the base 2. In this case, the corrosion resistance is improved, and the bonding strength between the base 2 and the film (first layer 3) is improved. The reason for this is presumed as follows.

Examples of the material of the base 2 include the same materials as those exemplified for the corrosion-resistant member 1A. When a description is made using an example in which the material of the base 2 is a ceramic, the ceramic (base 2) is composed of a polycrystalline sintered body. An M compound (for example, SiO₂), which is a compound of the metal element M, may be crystalline or amorphous. The compound layer 4 (M compound) having a uniform crystallinity is bonded to a portion, of the first layer 3, having a low crystallinity. When the M compound is bonded to the portion, of the first layer 3, having the low crystallinity, lattice defects, generated in a bonding portion between the M compound and the portion, of the first layer 3, having the low crystallinity, are reduced. Therefore, the bonding strength between the base 2 and the first layer 3, which are bonded via the M compound, is improved.

Rare earth element compounds such as Y₂O₃ are excellent in terms of corrosion resistance. The higher the crystallinity of the rare earth element compound, the better the corrosion resistance. Since the region 32, of the first layer 3, far from the base 2 has a high crystallinity, the region 32 is excellent in terms of corrosion resistance. Therefore, the surface side of the first layer 3 (rare earth oxide) of the corrosion-resistant member 1B is excellent in terms of corrosion resistance.

The compound layer 4 may have a more uniform crystallinity than the first layer 3. The compound layer 4 may be rephrased as a second layer 4. The compound layer 4 may be simply referred to as a film. The laminate body 1b may be rephrased as a second laminate body 1b.

The content of the metal element M contained in the compound layer 4 may be measured using the EDS attached to the TEM. The uniformity of the crystallinity of the compound layer 4 may be measured by electron diffraction using the TEM. The atomic number of the metal element M contained in the compound layer 4 may be smaller than the atomic number of the rare earth element contained in the first layer 3 as the main constituent.

In the bonding region between the first layer 3 and the compound layer 4, cations of the rare earth element constituting the first layer 3 and cations of the metal element M constituting the compound layer 4 are replaced or turned into a solid solution. In this case, the lattice defects in the bonding region are reduced. This is because when the atomic number is small, the ionic radius of the metal element M constituting the compound layer 4 tends to be small, and thus a residual stress generated in the first layer 3 is alleviated.

Examples of the rare earth element contained in the first layer 3 as the main constituent include the same rare earth elements as those exemplified for the corrosion-resistant member 1A. Examples of the metal element M contained in the compound layer 4 include Mg, Al, Si, Cr, Ni, Cu, Ga, Sr, Y, Ru, Pd, Sn, Hf, Ta, and W.

The rare earth element contained in the first layer 3 as the main constituent may be Y. The main constituent of the metal element M contained in the compound layer 4 may be Al.

The compound layer 4 may contain a rare earth element. The content of the rare earth element in the compound layer 4 may be less than the content of the rare earth element in the first layer 3.

In the above-described case, since the first layer 3 and the compound layer 4 contain the rare earth element, the chemical affinity between the first layer 3 and the compound layer 4 is improved. Therefore, the bonding strength between the first layer 3 and the compound layer 4 is improved. On the other hand, when the content of the rare earth element in the compound layer 4 becomes large, the effect of improving the mechanical strength of the compound layer 4 is not significant. Since the content of the rare earth element contained in the compound layer 4 is smaller than the content of the rare earth element contained in the first layer 3, a decrease in the mechanical strength of the compound layer 4 can be suppressed. As a result, a risk of the mechanical strength of the entire corrosion-resistant member 1B decreasing can be suppressed.

The first layer 3 may be exposed to the surface of the corrosion-resistant member 1B. Rare earth element compounds such as Y₂O₃ are excellent in terms of corrosion resistance. The higher the crystallinity of the rare earth element compound, the better the corrosion resistance. Since the region 32, of the first layer 3, far from the base 2 has a high crystallinity, the region 32 is excellent in terms of corrosion resistance. Thus, when the first layer 3 is exposed, the corrosion-resistant member 1B becomes excellent in terms of corrosion resistance.

The compound layer 4 may be amorphous. The region 31, of the first layer 3, close to the base 2 has a low crystallinity. The region, of the first layer 3, having the low crystallinity and the amorphous compound layer 4 are bonded to each other. When the region, of the first layer 3, having the low crystallinity and the amorphous compound layer 4 are bonded to each other, both have a low crystallinity. Thus, lattice defects generated therebetween are reduced. As a result, the bonding strength between the region, of the first layer 3, having the low crystallinity and the amorphous compound layer 4 is improved.

The measurement of whether the compound layer 4 is amorphous may be performed by electron diffraction using the TEM.

The rare earth element contained in the first layer 3 may be selected from at least one of Y, La, Nd, Sm, Eu, Gd, Dy, and Ho. The metal element M contained in the compound layer 4 may be selected from at least one of Mg, Al, Si, Cr, Ni, Cu, Ga, Sr, Y, Ru, Pd, Sn, Hf, Ta, and W.

Among the rare earth elements, compounds of Y, La, Nd, Sm, Eu, Gd, Dy, and Ho are relatively excellent in terms of corrosion resistance against the corrosive gas plasma. Except for a case where the rare earth elements contained in the first layer 3 and the compound layer 4 are the same, when the metal element M is Mg, Al, Si, Cr, Ni, Cu, Ga, Sr, Y, Ru, Pd, Sn, Hf, Ta, or W, the ionic radius of the cation of the metal element M contained in the compound layer 4 is smaller than the ionic radius of the cation of the rare earth element contained in the first layer 3. Thus, lattice defects in the bonding region between the first layer 3 and the compound layer 4 are reduced. Therefore, the bonding strength between the first layer 3 and the compound layer 4 is improved.

The rare earth element may be Y. Among the rare earth elements, an oxide of Y (Y₂O₃) is particularly excellent in terms of corrosion resistance against the corrosive gas plasma.

The compound layer 4 may contain an oxide of Al as the main constituent, or a composite oxide of Y and Al as the main constituent. The first layer 3 may have an amorphous region 33 composed of Y, Al, and O (oxygen) in a region thereof in contact with the compound layer 4. In this case, the bonding strength between the first layer 3 and the compound layer 4 is further improved. The reason for this is presumed as follows.

The compound layer 4 contains the oxide of Al as the main constituent, or the composite oxide of Y and Al as the main constituent. The first layer 3 contains the oxide of Y (Y₂O₃) as the main constituent. The first layer 3 has the amorphous region 33 composed of Y, Al, and O in the region thereof in contact with the compound layer 4. Thus, the lattice defects between the first layer 3 and the compound layer 4 are particularly reduced. As a result, the bonding strength between the first layer 3 and the compound layer 4 is further improved. The compound layer 4 is amorphous, and preferably contains the oxide of Al as the main constituent, or the composite oxide of Y and Al as the main constituent. When the compound layer 4 is amorphous and contains the oxide of Al as the main constituent or when the compound layer 4 contains the composite oxide of Y and Al as the main constituent, the lattice defects between the compound layer 4 and the first layer 3 are further reduced. Thus, the bonding strength between the first layer 3 and the compound layer 4 is particularly improved.

Whether or not the compound layer 4 contains the oxide of Al as the main constituent, or whether or not the compound layer 4 contains the composite oxide of Y and Al as the main constituent may be measured using the EDS attached to the TEM, or may be measured by electron diffraction using the TEM. The presence of the amorphous region 33 in the first layer 3 may be measured by electron diffraction using the TEM.

Examples of the oxide of Al contained in the compound layer 4 as the main constituent may include Al₂O₃. Examples of the composite oxide of Al and Y contained in the compound layer 4 as the main constituent may include YAlO₃, Y₂Al₄O₉, and Y₃Al₅O₁₂.

In the amorphous region 33, the content ratio of O may be the highest in terms of the atomic ratio. In the amorphous region 33, the content ratio of Al may be higher than the content ratio of Y in terms of the atomic ratio. Note that Y may be from 5 atomic % to 30 atomic %. Al may be from 10 atomic % to 40 atomic %. O may be from 40 atomic % to 80 atomic %.

An average thickness of the amorphous region 33 may be from 1 nm to 15 nm. The average thickness of the amorphous region 33 may be measured by the same measurement method as that for the average thickness of the first layer 3.

The average thickness of the compound layer 4 may be from 1 nm to 300 nm. When the lower limit is 1 nm, the lattice defects generated in the bonding region between the first layer 3 and the compound layer 4 are reduced. Therefore, the bonding strength between the first layer 3 and the compound layer 4 is improved. When the upper limit is 300 nm, particles generated at the time of exposure to a corrosive gas plasma can be reduced in size. The average thickness of the compound layer 4 may be measured by the same measurement method as that for the average thickness of the first layer 3.

The corrosion-resistant member 1C according to a non-limiting embodiment of the present disclosure will be described.

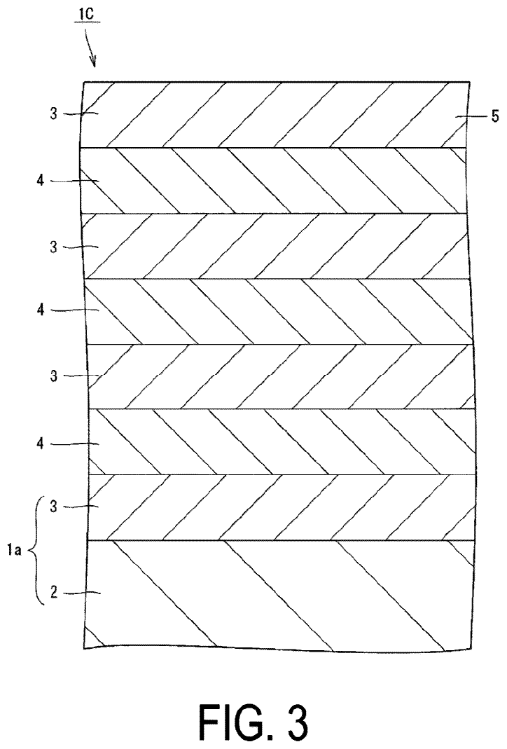

As in the example illustrated in FIG. 3, the corrosion-resistant member 1C includes the laminate body 1a, and the compound layers 4 of the metal element M and the first layers 3 alternately layered above the laminate body 1a. The compound layer 4 has a uniform crystallinity. The corrosion-resistant member 1C has a surface layer 5 made of the first layer 3 in a region, of the corrosion-resistant member 1C, farthest from the base 2.

In the corrosion-resistant member 1C, the compound layers 4 and the first layers 3, formed on the laminate body 1a, are alternately layered (bonded). In a bonding region where the compound layer 4 and the first layer 3 are layered in this order, a portion, of the first layer 3, having a low crystallinity in a region closer to the base 2 is bonded to the compound layer 4. In this bonding region, lattice defects are reduced. Thus, the bonding strength between the compound layer 4 and the first layer 3 is improved.

In a bonding region where the first layer 3 and the compound layer 4 are layered in this order, a portion, of the first layer 3, having a high crystallinity in a region farther from the base 2 is bonded to the compound layer 4. The region, of the first layer 3, having the high crystallinity has a higher mechanical strength than the region, of the first layer 3, having the low crystallinity. When the first layer 3 has the region having the high crystallinity, the mechanical strength of the first layer 3 is improved as compared with a case where the crystallinity of the entire first layer 3 is low. Thus, an occurrence of cracks from the first layer 3 can be suppressed while improving the bonding strength between the first layer 3 and the compound layer 4.

The metal element M contained in at least the compound layer 4 closest to the surface layer 5 may be Al. The rare earth element and Al have a high chemical bonding force. In a case where the surface layer 5 is the first layer 3, when the metal element M of the compound layer 4 closest to the surface layer 5 is Al, the bonding strength with the surface layer 5 is improved. Thus, even if the surface layer 5 is exposed to a corrosive gas plasma, particles are less likely generated from the surface layer 5.

The compound layer 4 may be amorphous. In this case, the first layers 3 and the compound layers 4 layered on top of each other a plurality of times can maintain a high bonding strength. The reason for this is presumed as follows.

The region 31, of any one of the first layers 3, close to the base 2 has a low crystallinity. The region, of the first layer 3, having the low crystallinity and the amorphous compound layer 4 are bonded to each other. When the region, of the first layer 3, having the low crystallinity and the amorphous compound layer 4 are bonded to each other, both have a low crystallinity. Thus, lattice defects generated therebetween are reduced. As a result, the bonding strength between the region, of the first layer 3, having the low crystallinity and the amorphous compound layer 4 is improved.

Due to the above-described actions and effects, in the region 32, of any of the first layers 3, far from the base 2, that is, a region having a high crystallinity, a residual stress generated by being bonding with the compound layer 4 is reduced. Therefore, even if the crystallinity of the region 32, of the any one of first layers 3, far from the base 2 is high, the bonding strength between the region, of the first layer 3, having the high crystallinity and the amorphous compound layer 4 is improved.

Due to the above-described actions and effects, the first layers 3 and the compound layers 4 layered on top of each other a plurality of times can maintain a state of a high bonding strength.

The plurality of first layers 3 in the corrosion-resistant member 1C may have the same composition, or may have different compositions. With respect to this point, the same also applies to the compound layers 4. That is, the plurality of compound layers 4 in the corrosion-resistant member 1C may have the same composition, or may have different compositions.

For example, the atomic number of the metal element M contained in at least one of the compound layers 4 among the plurality of compound layers 4 may be smaller than the atomic number of the rare earth element contained in the first layer 3 as the main constituent. At least one of the plurality of compound layers 4 may contain a rare earth element, and the content of the rare earth element in this compound layer 4 may be less than the content of the rare earth element in the first layer 3. At least one of the plurality of compound layers 4 may be amorphous.

The respective numbers of the compound layers 4 and the first layers 3 alternately layered above the laminate body 1a are not limited to specific values. For example, the number of the compound layers 4 may be set to be from 20 to 5000. The number of the first layers 3 may be set to be from 20 to 5000.

The corrosion-resistant member 1D according to a non-limiting embodiment of the present disclosure will be described.

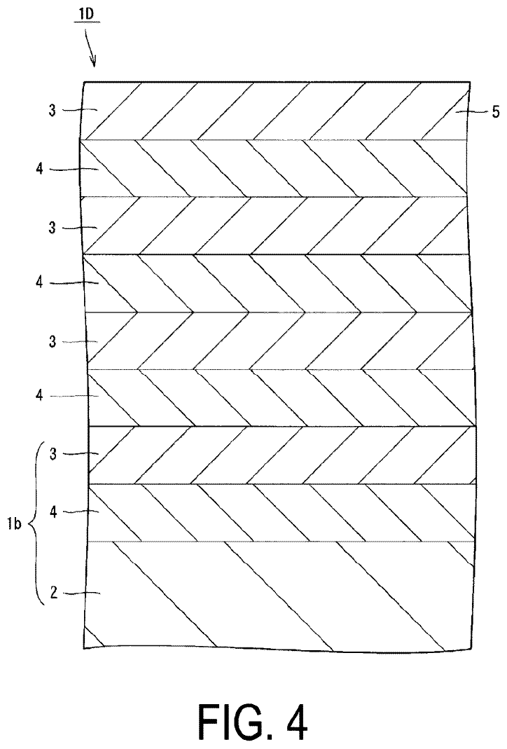

As in the example illustrated in FIG. 4, the corrosion-resistant member 1D includes the laminate body 1b, and the compound layers 4 of the metal element M and the first layers 3 alternately layered above the laminate body 1b. The compound layer 4 has a uniform crystallinity. The corrosion-resistant member 1D has the surface layer 5 made of the first layer 3 in a region, of the corrosion-resistant member 1D, farthest from the base 2. In this case, the occurrence of cracks from the first layer 3 can be suppressed while improving the bonding strength between the first layer 3 and the compound layer 4. The reason for this is the same as that described for the corrosion-resistant member 1C.

The respective numbers of the compound layers 4 and the first layers 3 alternately layered above the laminate body 1b are not limited to specific values. For example, the number of the compound layers 4 may be set to be from 20 to 5000. The number of the first layers 3 may be set to be from 20 to 5000.

The corrosion-resistant member 1E according to a non-limiting embodiment of the present disclosure will be described.

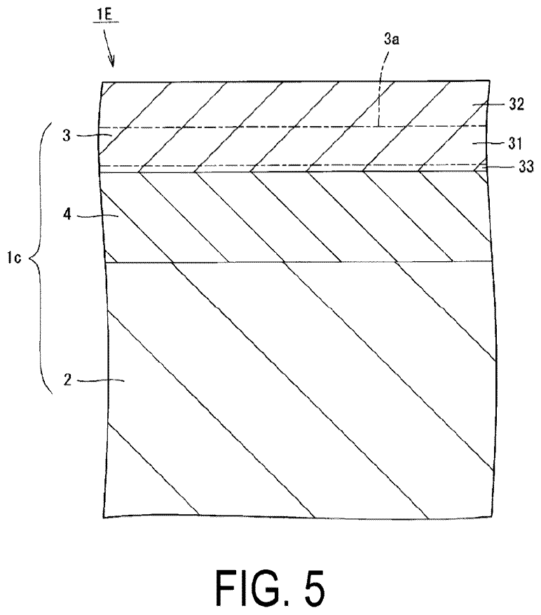

As in the example illustrated in FIG. 5, the corrosion-resistant member 1E is a laminate body 1c including the base 2, the compound layer 4 layered on the base 2 and composed of the metal element M, and the first layer 3 layered on the compound layer 4. The first layer 3 is composed of a rare earth element compound, which contains, as a main constituent, a rare earth element that is a metal element. The atomic number of the metal element M contained in the compound layer 4 is smaller than the atomic number of the rare earth element contained in the first layer 3 as the main constituent. In the first layer 3, the crystallinity of the region 31 close to the base 2 is lower than the crystallinity of the region 32 far from the base 2. In this case, the corrosion resistance is improved, and the bonding strength between the base 2 and the film (first layer 3) is improved. The reason for this is the same as that described for the corrosion-resistant members 1A and 1B. Note that the laminate body 1c may be rephrased as a third laminate body 1c.

The corrosion-resistant member 1F according to a non-limiting embodiment of the present disclosure will be described.

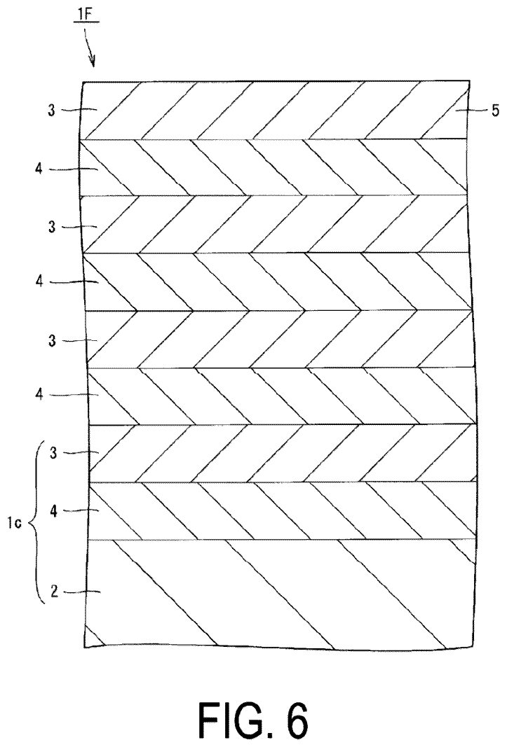

As in the example illustrated in FIG. 6, the corrosion-resistant member 1E includes the laminate body 1c, and the compound layers 4 of the metal element M and the first layers 3 alternately layered above the laminate body 1c. The atomic number of the metal element M contained in the compound layer 4 is smaller than the atomic number of the rare earth element contained in the first layer 3 as the main constituent. The corrosion-resistant member 1F has the surface layer 5 made of the first layer 3 in a region, of the corrosion-resistant member 1F, farthest from the base 2. In this case, the occurrence of cracks from the first layer 3 can be suppressed while improving the bonding strength between the first layer 3 and the compound layer 4. The reason for this is the same as that described for the corrosion-resistant members 1A to 1C.

The respective numbers of the compound layers 4 and the first layers 3 alternately layered above the laminate body 1c are not limited to specific values. For example, the number of the compound layers 4 may be set to be from 20 to 5000. The number of the first layers 3 may be set to be from 20 to 5000.

Examples of applications of the above-described corrosion-resistant members 1A to 1F include members exposed to a corrosive gas containing F, Cl, or Br, or a plasma of that gas, and members exposed to a corrosive material such as HF. In particular, the above-described corrosion-resistant members 1A to 1F may be applied as members that are used at a high temperature of about 300 to 700° C. in these gases and substances. Examples of the corrosive gas may include a CF₄ gas.

### Method for Manufacturing Corrosion-Resistant Member

A method for manufacturing a corrosion-resistant member according to a non-limiting embodiment of the present disclosure will be described.

First, the base 2 may be prepared. A method for manufacturing the base 2 made of a ceramic containing alumina as the main constituent will be described using an example.

An alumina (Al₂O₃) A powder having an average particle diameter from 0.4 μm to 0.6 μm and an alumina B powder having an average particle diameter approximately from 1.2 μm to 1.8 μm are prepared. In addition, a silicon oxide (SiO₂) powder is prepared as a Si source, and a calcium carbonate (CaCO₃) powder is prepared as a Ca source. Note that, as the silicon oxide powder, a fine powder having an average particle diameter of 0.5 μm or less is prepared. In order to obtain an alumina ceramic containing Mg, a magnesium hydroxide powder is used. Note that, in the following description, powders other than the alumina A powder and the alumina B powder are collectively referred to as first sub-component powders.

Subsequently, a predetermined amount of each of the first sub-component powders is weighed. The alumina A powder and the alumina B powder are then weighed in a mass ratio from 40:60 to 60:40 so that the content of Al converted to Al₂O₃ is 99.4 mass % or greater out of 100 mass % of the components constituting the obtained ceramic, thereby obtaining a blended alumina powder. In addition, the first sub-component powders are weighed so that, after first determining the amount of Na in the blended alumina powder and converting, to Na₂O, the amount of Na when made into a ceramic, the ratio of this converted value to the value of the components constituting the first sub-component powders (in this example, Si, Ca, and the like) converted to oxide is 1.1 or less.

Then, with respect to 100 total parts by mass of the blended alumina powder and the first sub-component powders, from 1 to 1.5 parts by mass of a binder such as polyvinyl alcohol (PVA), 100 parts by mass of a solvent, and from 0.1 to 0.55 parts by mass of a dispersing agent are provided to an agitation device and mixed and agitated to obtain a slurry.

Subsequently, the slurry is spray-granulated to obtain granules, and the granules are molded into a predetermined shape by a powder press molding device, an isostatic press molding device, or the like, and machined as necessary to obtain a powder compact.

The powder compact is then fired at a firing temperature from 1500° C. to 1700° C. and with a retention time from 4 hours to 6 hours to obtain a sintered body. Then, the surface of the sintered body on which the film is to be formed is ground to obtain a ground surface, and the ground surface is subsequently roughly polished by using diamond abrasive grains having an average particle diameter of 4 μm or greater and a polishing disk made of cast iron. In the rough polishing, after the diamond abrasive grains having a large average particle diameter are used, diamond abrasive grains having a small average particle diameter may be used. Subsequently, the surface is finished by using diamond abrasive grains having an average particle diameter from 1 μm to 5 μm and a polishing plate made of tin. As a result, the base 2 can be obtained. After the finishing, the surface may be polished by using colloidal silica, ceria, or alumina abrasive grains, and a polishing pad obtained by impregnating a nonwoven fabric made of polyester fibers with polyurethane. The average particle diameter of the colloidal abrasive grains described above is, for example, from 20 μm to 50 μm.

A method for forming a film will be described using an example in which a Y₂O₃ layer is formed as the first layer 3.

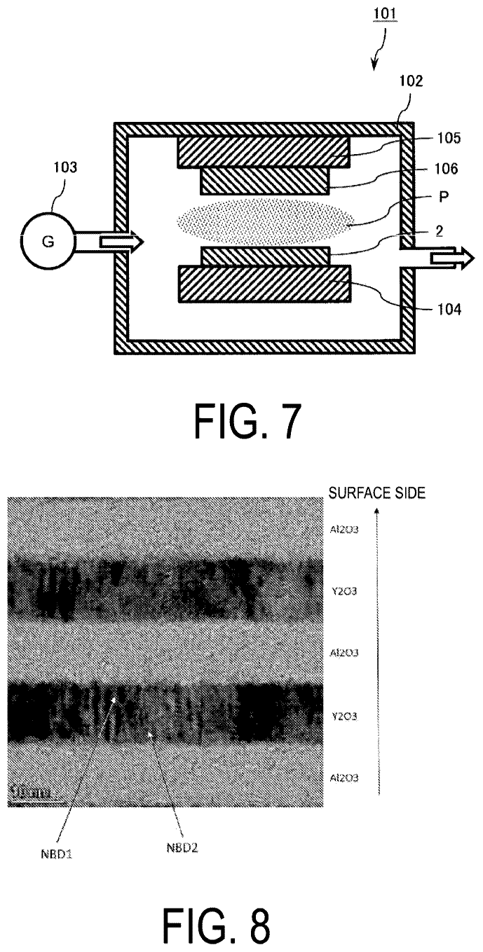

As in the example illustrated in FIG. 7, a sputtering device 101 may be used to form a film. The sputtering device 101 includes a chamber 102, a gas supply source 103 leading into the chamber 102, an anode electrode 104 and a cathode electrode 105 located inside the chamber 102, and a target 106 connected to the cathode electrode 105 side.

First, the base 2 is installed on the anode electrode 104 side inside the chamber 102. The target 106 containing a rare earth element, in this case, metal yttrium as the main constituent is installed on the cathode electrode 105 side. In this state, the inside of the chamber 102 is depressurized by an exhaust pump, and argon and oxygen are supplied as a gas G from the gas supply source 103. Here, the pressure of the supplied argon gas is from 0.1 Pa to 2 Pa. The temperature inside the chamber 102 is from 50°° C. to 400° C.

Then, an electric field is applied between the anode electrode 104 and the cathode electrode 105 by a power supply to generate and sputter a plasma P1, thereby forming a metal yttrium film on the surface of the base 2. Note that the power supplied from the power supply may be either high-frequency power or direct current power. The thickness per formation is sub-nm.

A plasma P2 is then generated to oxidize the metal yttria film. Then, a Y₂O₃ layer serving as the first layer 3 can be formed by alternately forming the metal yttrium oxide film and executing an oxidization process to laminate the film so that an average thickness of the film is from 1 nm to 1000 nm. Note that the reference sign P illustrated in FIG. 7 represents the plasma P1 or the plasma P2.

In the plasma P1, among optical spectra of the plasma P1, a first spectrum having the highest intensity is located at wavelengths from 390 nm to 430 nm, and other optical spectra (second spectrum, third spectrum, and fourth spectrum in descending order of intensity) are located at wavelengths from 300 nm to 700 nm.

In the plasma P2, among optical spectra of the plasma P2, a first spectrum having the highest intensity is located at wavelengths from 500 nm to 550 nm, and other optical spectra (second spectrum, third spectrum, and fourth spectrum in descending order of intensity) are located at wavelengths from 380 nm to 820 nm.

In order to form an Y₂O₃ layer having a low crystallinity, the temperature inside the chamber 102 may be lowered. In order to form an Y₂O₃ layer having a high crystallinity, the temperature inside the chamber 102 may be increased.

Other films such as the compound layer 4 may be formed in the same manner as the Y₂O₃ layer. For example, when an Al₂O₃ layer is formed as the compound layer 4, the target 106 containing Al as the main constituent may be used. In order to form the amorphous compound layer 4, the temperature inside the chamber 102 may be lowered. In order to form the amorphous region 33, after forming the compound layer 4, when the first layer 3 is formed on the compound layer 4, the temperature inside the chamber 102 may be initially lowered and the temperature inside the chamber 102 may be gradually increased to form the film. The embodiments according to the present disclosure are exemplified above.

However, the present disclosure is not limited to the embodiments described above, and naturally includes variations within a scope that does not deviate from the spirit of the present disclosure.

For example, a corrosion-resistant member may have the following configuration.
(1) A corrosion-resistant member is a laminate body including a base, and a first layer layered on the base. The first layer is composed of a rare earth element compound, which contains, as a main constituent, a rare earth element that is a metal element. In the first layer, a crystallinity of a region close to the base is lower than a crystallinity of a region far from the base.
(2) A corrosion-resistant member is a laminate body including a base, a compound layer layered on the base and composed of a metal element M, and a first layer layered on the compound layer. The first layer is composed of a rare earth element compound, which contains, as a main constituent, a rare earth element that is a metal element. The compound layer has a uniform crystallinity. In the first layer, a crystallinity of a region close to the base is lower than a crystallinity of a region far from the base.
(3) The corrosion-resistant member according to (1) or (2) described above may include the laminate body, and the compound layer of the metal element M and the first layer alternately layered above the laminate body. The compound layer may have a uniform crystallinity, and a surface layer made of the first layer may be provided in a region, of the corrosion-resistant member, farthest from the base.
(4) In the corrosion-resistant member according to (2) or (3) described above, an atomic number of the metal element M contained in the compound layer may be smaller than an atomic number of the rare earth element contained in the first layer as the main constituent.
(5) A corrosion-resistant member is a laminate body including a base, a compound layer layered on the base and composed of a metal element M, and a first layer layered on the compound layer. The first layer is composed of a rare earth element compound, which contains, as a main constituent, a rare earth element that is a metal element. An atomic number of the metal element M contained in the compound layer is smaller than an atomic number of the rare earth element contained in the first layer as the main constituent. In the first layer, a crystallinity of a region close to the base is lower than a crystallinity of a region far from the base.
(6) The corrosion-resistant member according to (1) or (5) described may include the laminate body, and the compound layer of the metal element M and the first layer alternately layered above the laminate body. The atomic number of the metal element M contained in the compound layer may be smaller than the atomic number of the rare earth element contained in the first layer as the main constituent, and a surface layer made of the first layer may be provided in a region, of the corrosion-resistant member, farthest from the base.
(7) In the corrosion-resistant member according to (3) or (6) described above, the metal element M contained in at least the compound layer closest to the surface layer may be Al.
(8) In the corrosion-resistant member according to any one of (2) to (7) described above, the compound layer may contain a rare earth element, and a content of the rare earth element in the compound layer may be less than a content of the rare earth element in the first layer.
(9) In the corrosion-resistant member according to any one of (1) to (8) described above, the first layer may be exposed to a surface of the corrosion-resistant member.
(10) In the corrosion-resistant member according to any one of (2) to (9) described above, the compound layer may be amorphous.
(11) In the corrosion-resistant member according to any one of (1) to (10) described above, the rare earth element compound may be an oxide.
(12) In the corrosion-resistant member according to any one of (2) to (11) described above, the rare earth element included in the first layer may be selected from at least one of Y, La, Nd, Sm, Eu, Gd, Dy, and Ho, and the metal element M contained in the compound layer may be selected from at least one of Mg, Al, Si, Cr, Ni, Cu, Ga, Sr, Y, Ru, Pd, Sn, Hf, Ta, and W.
(13) In the corrosion-resistant member according to (12) described above, the rare earth element may be Y.
(14) In the corrosion-resistant member according to any one of (1) to (13) described above, the base may be made of a ceramic.
(15) In the corrosion-resistant member according to any one of (1) to (14) described above, the base may contain alumina as a main constituent, and the first layer may contain an oxide of Y as a main constituent and may further contain a composite oxide of Y and Al.
(16) In the corrosion-resistant member according to any one of (2) to (15) described above, the compound layer may contain an oxide of Al as a main constituent, or may contain a composite oxide of Y and Al as a main constituent. The first layer may have an amorphous region composed of Y, Al, and O in a region, of the first layer, in contact with the compound layer.
(17) In the corrosion-resistant member according to any one of (2) to (16) described above, an average thickness of the compound layer may be from 1 nm to 300 nm.

In the corrosion-resistant member 1F, the laminate body 1c may be used instead of the laminate body 1a.

The present disclosure will be described in detail below using examples, but the present disclosure is not limited to the following examples.

### EXAMPLES

### Example 1

According to the manufacturing method described above, Y₂O₃ layers (50 layers in total) serving as the first layers and Al₂O₃ layers (49 layers in total) serving as the compound layers were alternately layered on a base composed of Al₂O₃ to obtain a corrosion-resistant member having an Y₂O₃ layer as the surface layer. Note that the average thickness of the first layers (Y₂O₃ layers) was 11 nm, and the average thickness of the compound layers (Al₂O₃ layers) was 11 nm.

A lattice fringe of the Y₂O₃ layer was confirmed in a partially enlarged TEM photograph of the obtained corrosion-resistant member (see FIG. 8). Therefore, it was confirmed that a region having a crystallinity was present in the Y₂O₃ layer.

In the Y₂O₃ layer having the average thickness of 11 nm, the results of electron diffraction patterns were different between the surface side and the base side (see FIGS. 9 and 10). From this result, it was confirmed that, in the Y₂O₃ layer, the region (NBD2) close to the base had a low crystallinity, and the region (NBD1) far from the base had a high crystallinity.

As a result of electron diffraction by the TEM, the first layer had an amorphous region composed of Y, Al, and O in a region thereof in contact with the compound layer. The average thickness of the amorphous regions was 4 nm. In the amorphous region, O was 60.28 atomic %, Al was 24.72 atomic %, and Y was 15.00 atomic %. As a result of electron diffraction by the TEM, the compound layer was found to have a uniform crystallinity.

### Example 2

According to the above-described manufacturing method, a plurality of each of the following Samples No. 1 and No. 2 were obtained.

Sample No. 1: A corrosion-resistant member in which an Y₂O₃ layer (having an average thickness of 1.1 μm) as the first layer is formed on a base composed of Al₂O₃.

Sample No. 2: A corrosion-resistant member in which Y₂O₃ layers (having an average thickness of 11 nm) serving as the first layers and Al₂O₃ layers (having an average thickness of 11 nm) serving as the compound layers are alternately layered on a base composed of Al₂O₃, and an Y₂O₃ layer was formed as the surface layer. Note that the Y₂O₃ layers are 50 layers in total, and the Al₂O₃ layers are 49 layers in total. The average thickness of the entire film is 1.1 μm.

Samples No. 1 and No. 2 were measured in the same manner as in Example 1. As a result of the measurements, it was confirmed that, in the Y₂O₃ layer, a region close to the base had a low crystallinity, and a region far from the base had a high crystallinity. The compound layer had a uniform crystallinity.

Samples No. 1 and No. 2 were evaluated for adhesion strength and plasma resistance. Evaluation methods for each of the above are as follows.

### Evaluation Method for Adhesion Strength

Scratch tests were performed three times for each of the samples using a Revetest Scratch Tester (S/N: 27-486) manufactured by CSM Instruments. A diamond indenter (N2-5168) having a tip curvature radius of 200 μm was used as an indenter.

The test conditions are as follows.
Begin load: 0.9 N
Loading rate: 100 N/min
Scratch speed: 10 mm/min
AE sensitivity: 9
Note that the adhesion strength (N) of each of the samples is an average value of three measured values.

### Evaluation Method for Plasma Resistance

A masking tape is attached to a part of the surface layer for masking. A step generated between before and after plasma exposure is measured by an optical surface texture measuring instrument. The step is a thickness of the film reduced by the exposure to the plasma. The measurement method for the step is as follows. First, a masking tape is attached to a part of the film surface, and then the film surface is exposed to plasma. After the exposure to the plasma, the masking tape is removed. A step is formed between the surface (unexposed surface) from which the masking tape has been peeled off, and the surface (after the exposure) exposed to the plasma. The dimension of this step is measured. The smaller the step, the better the plasma resistance.

Plasma exposure conditions are as follows.
Partial pressure (Pa) of CF₄ gas: 9 Pa
CF₄ gas flow rate (L/min): 100 sccm
Exposure time to CF₄ gas: 4 hr
Output: 900 W
Material of masking tape: Kapton tape
Note that a reactive ion etching (RIE) device was used for the plasma exposure.
The measurement results are as follows.
Adhesion Strength
Sample No. 1:24.2 N
Sample No. 2:34.2 N
Plasma Resistance
Sample No. 1:0.0792 μm

Sample No. 2:0.0902 μm

Samples No. 1 and No. 2 of the present disclosure were excellent in terms of adhesion strength and plasma resistance. From this result, it can be said that, according to Samples No. 1 and No. 2, the corrosion resistance is improved and the bonding strength between the base and the film is improved.

As a comparative example, a sample made of a sintered body of yttrium oxide (Y₂O₃) was used to evaluate the plasma resistance under the same conditions as in Example 2. As a result, in the case of the yttrium oxide sintered body, the step was as large as 0.11 μm, and the corrosion resistance was poor.

### REFERENCE SIGNS

1A Corrosion-resistant member
1B Corrosion-resistant member
1C Corrosion-resistant member
1D Corrosion-resistant member
1E Corrosion-resistant member
1F Corrosion-resistant member
1a Laminate body (first laminate body)
1b Laminate body (second laminate body)
1c Laminate body (third laminate body)
2 Base
3 First layer
31 Region close to base
32 Region far from base
33 Amorphous region
3a Center
4 Compound layer (second layer)
5 Surface layer
101 Sputtering device
102 Chamber
103 Gas supply source
104. Anode electrode
105. Cathode electrode
106 Target

1. A corrosion-resistant member comprising:
a laminate body comprising:
a base, and
a first layer on the base, wherein
the first layer is composed of a rare earth element compound, which contains, as a main constituent, a rare earth element that is a metal element, and
in the first layer, a crystallinity of a region close to the base is lower than a crystallinity of a region far from the base.

2. A corrosion-resistant member comprising:
a laminate body comprising:
a base,
a compound layer on the base and composed of a metal element M, and
a first layer on the compound layer, wherein
the first layer is composed of a rare earth element compound, which contains, as a main constituent, a rare earth element that is a metal element,
the compound layer has a uniform crystallinity, and
in the first layer, a crystallinity of a region close to the base is lower than a crystallinity of a region far from the base.

3. The corrosion-resistant member according to claim 1, comprising:
the laminate body; and
a compound layer of the metal element M and the first layer alternately layered above the laminate body, wherein
the compound layer has a uniform crystallinity, and
a surface layer made of the first layer is provided in a region, of the corrosion-resistant member, farthest from the base.

4. The corrosion-resistant member according to claim 2, wherein
an atomic number of the metal element M contained in the compound layer is smaller than an atomic number of the rare earth element contained in the first layer as the main constituent.

5. A corrosion-resistant member comprising:
a laminate body comprising:
a base,
a compound layer layered on the base and composed of a metal element M, and
a first layer layered on the compound layer, wherein
the first layer is composed of a rare earth element compound, which contains, as a main constituent, a rare earth element that is a metal element,
an atomic number of the metal element M contained in the compound layer is smaller than an atomic number of the rare earth element contained in the first layer as the main constituent, and
in the first layer, a crystallinity of a region close to the base is lower than a crystallinity of a region far from the base.

6. The corrosion-resistant member according to claim 1, comprising:
the laminate body; and
a compound layer of the metal element M and the first layer alternately layered above the laminate body, wherein
an atomic number of the metal element M contained in the compound layer is smaller than the atomic number of the rare earth element contained in the first layer as the main constituent, and
a surface layer made of the first layer is provided in a region, of the corrosion-resistant member, farthest from the base.

7. The corrosion-resistant member according to claim 3, wherein
the metal element M contained in at least the compound layer closest to the surface layer is Al.

8. The corrosion-resistant member according to claim 2, wherein
the compound layer contains a rare earth element, and
a content of the rare earth element in the compound layer is less than a content of the rare earth element in the first layer.

9. The corrosion-resistant member according to claim 1, wherein
the first layer is exposed to a surface of the corrosion-resistant member.

10. The corrosion-resistant member according to claim 2, wherein
the compound layer is amorphous.

11. The corrosion-resistant member according to claim 1, wherein
the rare earth element compound is an oxide.

12. The corrosion-resistant member according to claim 2, wherein
the rare earth element in the first layer is selected from at least one of Y, La, Nd, Sm, Eu, Gd, Dy, and Ho, and
the metal element M contained in the compound layer is selected from at least one of Mg, Al, Si, Cr, Ni, Cu, Ga, Sr, Y, Ru, Pd, Sn, Hf, Ta, and W.

13. The corrosion-resistant member according to claim 12, wherein
the rare earth element is Y.

14. The corrosion-resistant member according to claim 1, wherein
the base is made of a ceramic.

15. The corrosion-resistant member according to claim 1, wherein
the base contains alumina as a main constituent, and
the first layer contains an oxide of Y as a main constituent and further contains a composite oxide of Y and Al.

16. The corrosion-resistant member according to claim 2, wherein
the compound layer contains an oxide of Al as a main constituent, or contains a composite oxide of Y and Al as a main constituent, and
the first layer has an amorphous region composed of Y, Al, and O in a region, of the first layer, in contact with the compound layer.

17. The corrosion-resistant member according to claim 2, wherein
an average thickness of the compound layer is from 1 nm to 300 nm.

18. The corrosion-resistant member according to claim 2, comprising:
the laminate body; and
the compound layer and the first layer alternately layered above the laminate body, wherein
a surface layer made of the first layer is provided in a region, of the corrosion-resistant member, farthest from the base.

19. The corrosion-resistant member according to claim 18, wherein
an atomic number of the metal element M contained in the compound layer is smaller than an atomic number of the rare earth element contained in the first layer as the main constituent.
